(19) United States
(12) Patent Application Publication
(10) Pub. No.: US 2016/0155514 A1
(43) Pub. Date: Jun. 2, 2016

(54) SYSTEM AND METHOD OF TESTING AND IDENTIFYING MEMORY DEVICES

(71) Applicant: KingTiger Technology (Canada) Inc., Markham (CA)

(72) Inventors: Bosco Chun Sang Lai, Markham (CA); Sunny Lai-Ming Chang, Markham (CA); Eric Sin Kwok Chiu, Mississauga (CA); Xiaoyi Cao, Shenzhen (CN); Frank Xiaoyong Tian, Toronto (CA); Jiyi Ren, Vaughan (CA); Shaodong Zhou, Shenzhen (CN); Lei Zhang, Shenzhen (CN)

(73) Assignee: KingTiger Technology (Canada) Inc., Markham (CA)

(21) Appl. No.: 14/955,144

(22) Filed: Dec. 1, 2015

Related U.S. Application Data
(60) Provisional application No. 62/085,993, filed on Dec. 1, 2014.

(51) Int. Cl. G11C 29/44; G11C 29/38

(52) U.S. Cl. CPC G11C 29/44; G11C 29/38

(57) ABSTRACT

Various embodiments are described herein for testing memory devices more effectively and taking corrective action or for identifying memory devices. For example, a particular set of memory cells may be used for testing and/or for identifying a memory device. In other cases, memory testing may be done with a particular subset of test patterns.

### CROSS-REFERENCE TO RELATED APPLICATION

This application claims the benefit and priority of U.S. Provisional Patent Application Ser. No. 62/085,993, filed on Dec. 1, 2014. The entire contents of such application are hereby incorporated by reference.

### TECHNICAL FIELD

Embodiments described herein relate generally to computing systems and computer memory for use in computing systems.

### BACKGROUND

Applicant's U.S. patent application Ser. No. 14/011,508, published as U.S. Patent Publication No. 2014/0068360, both documents which are hereby incorporated herein by reference, disclose embodiments of systems and methods that are referred to generally herein as Intelligent Memory Surveillance (“iMS”). More specifically, those documents describe systems and methods directed to “memory protection”, addressing how a computing system may be protected from harmful consequences arising from a memory failure, such as a computer crash. Systems and methods applicable to testing, for example, dynamic random access memory (DRAM) memories were discussed.

### SUMMARY OF VARIOUS EMBODIMENTS

In a broad aspect, at least one embodiment described herein provides a method of a method of identifying a memory device that is used by a computing system, the memory device having memory blocks containing memory cells, the method comprising testing the memory device to determine weakest n memory cells based on performance testing; and creating an identifier for the memory device based on using memory addresses of the n weakest memory cells.

In at least one embodiment, n has a value determined based on how many memory cells are within the memory device, with n being smaller for a larger memory device compared to a smaller memory device.

In at least one embodiment, the method further comprises concatenating the memory addresses of the n weakest memory cells to create the identifier.

In at least one embodiment, the method further comprises applying at least one of a hash function and an encryption method on the memory addresses of the n weakest memory cells to create the identifier.

In at least one embodiment, the method further comprises ranking the n weakest memory cells starting with the weakest memory cell and ordering the memory addresses of the n weakest memory cells according to the ranking and creating the identifier based on the ranked memory addresses.

In at least one embodiment, there is provided a computing system that creates an identifier for a memory device having memory blocks with memory cells, the computing system comprising a memory controller that is coupled to the memory device and is configured to enable creation of the identifier by performing the method of identifying a memory device as specified herein and an operating system for controlling operation of the computing system.

In at least one embodiment, there is provided a computer readable medium comprising a plurality of instructions that are executable by a processor of a computing system, wherein the plurality of instructions implement the method of identifying a memory device as specified herein.

In another broad aspect, at least one embodiment described herein provides a method of testing a memory device that is used by a computing system, the memory device having memory blocks having memory cells, the method comprising initializing test parameters to reduce how much testing is done compared to a comprehensive memory test; testing performance for the memory device using tests defined by the test parameters to identify memory blocks having at least one faulty memory cell; and performing a corrective action on the identified memory blocks.

In at least one embodiment, the initialization act comprises selecting faulty memory cells that resulted in a crash of an operating system of the computing system, the testing and the performing of the corrective action occurs during a bootup process of the computing system after the operating system crash and the performing comprises repairing or isolating the faulty memory cells that resulted in the crash.

In at least one embodiment, the initialization comprises determining a set of n weakest memory cells or a set of n randomly chosen memory cells to act as n representative memory cells for the memory device; and performing the testing on the set of n representative memory cells.

In at least one embodiment, if the testing of the n representative memory cells determines an abrupt deterioration of the n representative memory cells, then the method further comprises performing comprehensive memory testing.

In at least one embodiment, the method further comprises storing the test results in a test statistics database and comparing test results taken at different times to determine how quickly the memory device is deteriorating.

In at least one embodiment, the act of initializing the testing comprises selecting a smaller subset of test patterns that are more likely to locate faulty memory cells based on test statistics from previous testing.

In at least one embodiment, the corrective action comprises repairing the at least one faulty memory cell if it is located in a high priority level memory block.

In at least one embodiment, the corrective action comprises repairing faulty memory cells until all repair resources are exhausted or meet a resource threshold where the repair resources are reserved for future repair of memory cells in a higher priority level memory area.

In at least one embodiment, the method further comprises determining a priority level for a given memory cell based on a highest standard of performance requirements met by a given memory block that includes the given memory cell.

In at least one embodiment, the method further comprises assigning a high priority level for a given memory cell that is used in the bootup of the computing system or the given memory cell is used by an operating system of the computing system.

In at least one embodiment, the method further comprises assigning a high priority level for a given memory cell according to a risk of system crash due to a memory failure of the given memory cell.

In at least one embodiment, the method comprises assigning a highest priority level for a given memory cell used to store system boot instructions, assigning a second highest priority level to the given memory cell when it stores operating system instructions, assigning a third highest priority level to the given memory cell when it stores user programs and assigning a fourth highest priority level to the given memory cell when it stores database records.

In at least one embodiment, the corrective action comprises masking the identified memory block having at least one faulty memory cell so that it is isolated and not used during operation if the at least one memory cell cannot be repaired or the at least one memory cell resides in a lower priority level memory area.

In at least one embodiment, the act of testing comprises performing more rigorous above-standard tests in the field after the memory device has been deployed from manufacturing.

In at least one embodiment, the method comprises a two stage test with a first stage where the act of initializing comprises selecting a smaller number of memory cells to test and a smaller number of test patterns for testing compared to a comprehensive memory test and the second stage comprises performing the testing.

In another broad aspect, at least one embodiment described herein provides a computing system that tests performance for a memory device having memory blocks with memory cells, the computing system comprising a memory controller that is coupled to the memory device and is configured to enable testing of the memory device; an operating system for controlling operation of the computing system; and test components that are configured to test performance of the memory device using a reduced amount of testing compared to a comprehensive memory test and to perform a corrective action on memory cells located in one or more of the memory blocks.

In at least one embodiment, the test components are configured to test a set of n representative cells for a given memory block to determine the performance of the given memory block, the set of n representative cells representing n weakest memory cells or n randomly selected memory cells.

In at least one embodiment, the test components are configured to perform testing using a smaller subset of test patterns than a comprehensive memory test that are more likely to locate faulty memory cells based on test statistics from previous testing.

In at least one embodiment, the corrective action comprises repairing or masking and the test components are configured to repair the at least one faulty memory cell if it is located in a high priority level memory block or mask the memory block containing the at least one faulty memory cell if it is a low priority level memory block.

In at least one embodiment, the high priority level memory block is an area of the memory device that is used in the bootup of the computing system or that is used by the operating system.

In at least one embodiment, the test components are configured to select a smaller number of memory cells in a given memory block to test and use a smaller number of test patterns for testing compared to the comprehensive memory test.

In another broad aspect, at least one embodiment described herein provides a computer readable medium comprising a plurality of instructions that are executable by a processor of a computing system, wherein the plurality of instructions implement a method of testing a performance of a memory device as specified herein.

In another broad aspect, at least one embodiment described herein provides a computer readable medium (CRM) comprising a plurality of instructions that are executable by a processor of a computing system, wherein the plurality of instructions implement a method of testing a performance of a memory device, wherein the method comprises: initializing test parameters to reduce how much testing is done compared to a comprehensive memory test; testing performance for the memory device using tests defined by the test parameters to identify memory blocks having at least one faulty memory cell; and performing a corrective action on the identified memory blocks.

In at least one CRM embodiment, the method further comprises selecting n representative cells for a given memory block using n weakest memory cells or n random memory cells of the given memory block; and testing the set of n representative cells to determine the performance of the given memory block.

In at least one CRM embodiment, the method comprises performing testing using a smaller subset of test patterns than a comprehensive memory test that are more likely to locate faulty memory cells based on test statistics from previous testing.

In at least one CRM embodiment, the method comprises performing repairing or masking as the corrective action, the repairing being done on the at least one faulty memory cell if it is located in a high priority level memory block and the masking being done if at least one faulty memory cell is in a low priority level memory block.

In at least one CRM embodiment, the method comprises selecting a smaller number of memory cells in a given memory block to test and using a smaller number of test patterns for testing compared to the comprehensive memory test.

Other features and advantages of the present application will become apparent from the following detailed description taken together with the accompanying drawings. It should be understood, however, that the detailed description and the specific examples, while indicating one or more embodiments of the application, are given by way of illustration only, since various changes and modifications within the spirit and scope of the application will become apparent to those skilled in the art from this detailed description.

### BRIEF DESCRIPTION OF THE DRAWINGS

For a better understanding of the example embodiments described herein, and to show more clearly how these various embodiments may be carried into effect, reference will now be made, by way of example, to the accompanying drawings which show at least one example embodiment, and which are now described. The drawings are not intended to limit the scope of the teachings described herein.

FIG. 1 shows an example process of memory aging in which the memory performance decreases with time (shown for two different memory parameters).

FIG. 2 shows an example embodiment of a quick memory test method for testing a memory device.

FIG. 3 shows an example embodiment of an effective memory test method for testing a memory device.

FIGS. 4A and 4B show example data valid windows for two timing parameters of memory where the dimensions of the data valid windows decrease with memory aging.

FIG. 5 shows an example embodiment of a computing system with example memory testing components in accordance with the teachings herein.

FIG. 6 shows an example of repaired memory cells and masked-off memory cells when memory cells having memory failures are identified and processed.

FIG. 7 shows an example of the weakest memory cells that have been identified for a memory device.

FIG. 8 shows an example of memory cells that failed resulting in a blue screen failure causing bootup of a computer system and memory testing to repair or mask the failed memory cells.

Further aspects and features of the example embodiments described herein will appear from the following description taken together with the accompanying drawings.

### DESCRIPTION OF EXAMPLE EMBODIMENTS

Various systems, devices or methods will be described below to provide an example of at least one embodiment of the claimed subject matter. No embodiment described herein limits any claimed subject matter and any claimed subject matter may cover systems, devices or methods that differ from those described herein. The claimed subject matter is not limited to systems, devices or methods having all of the features of any one process or device described below or to features common to multiple or all of the systems, devices or methods described herein. It is possible that a system, device or method described herein is not an embodiment of any claimed subject matter. Any subject matter that is disclosed in a system, device or method described herein that is not claimed in this document may be the subject matter of another protective instrument, for example, a continuing patent application, and the applicants, inventors or owners do not intend to abandon, disclaim or dedicate to the public any such subject matter by its disclosure in this document.

It should also be noted that the terms “coupled” or “coupling” as used herein can have several different meanings depending in the context in which these terms are used. For example, the terms coupled or coupling can have a mechanical, electrical or communicative connotation. For example, as used herein, the terms coupled or coupling can indicate that two or more elements or devices can be directly connected to one another or connected to one another through one or more intermediate elements or devices via an electrical element or electrical signal depending on the particular context. Furthermore, the term “communicative coupling” indicates that an element or device can electrically, or wirelessly send data to or receive data from another element or device depending on the particular embodiment.

It should also be noted that, as used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

The example embodiments of the systems, devices or methods described in accordance with the teachings herein may be implemented as a combination of hardware or software. For example, the embodiments described herein may be implemented, at least in part, by using one or more computer programs, executing on one or more programmable devices comprising at least one processing element, and at least one data storage element (including volatile and non-volatile memory and a memory buffer). These devices may also have at least one input device (e.g., a keyboard, a mouse, a touchscreen, and the like), and at least one output device (e.g., a display screen, a printer, a wireless radio, and the like) depending on the nature of the device.

It should also be noted that there may be some elements that are used to implement at least part of the embodiments described herein that may be implemented via software that is written in a high-level procedural language such as object oriented programming. The program code may be written in C, C⁺⁺ or any other suitable programming language and may comprise modules or classes, as is known to those skilled in object oriented programming. Alternatively, or in addition thereto, some of these elements implemented via software may be written in assembly language, machine language or firmware as needed.

At least some of these software programs may be stored on a storage media (e.g., a computer readable medium such as, but not limited to, ROM, magnetic disk, optical disc) or a device that is readable by a general or special purpose programmable device. The software program code, when read by the programmable device, configures the programmable device to operate in a new, specific and predefined manner in order to perform at least one of the methods described herein.

Furthermore, at least some of the programs associated with the systems and methods of the embodiments described herein may be capable of being distributed in a computer program product comprising a computer readable medium that bears computer usable instructions, such as program code, for one or more processors. The program code may be preinstalled and embedded during manufacture and/or may be later installed as an update for an already deployed computing system. The medium may be provided in various forms, including non-transitory forms such as, but not limited to, one or more diskettes, compact disks, tapes, chips, and magnetic and electronic storage. In alternative embodiments, the medium may be transitory in nature such as, but not limited to, wire-line transmissions, satellite transmissions, internet transmissions (e.g. downloads), media, digital and analog signals, and the like. The computer useable instructions may also be in various formats, including compiled and non-compiled code.

JEDEC memory standards define the specifications for DDR4 SDRAM memory circuits that include a new feature called “Post Package Repair” or “PPR” (these memory circuits are also referred to herein as “self-repairing” memory devices), which allows for a partial repair of failed memory cells in the field (e.g., while the memory devices are in actual use, after production). Memory devices typically will comprise at least some redundant memory cells. In general, the self-repair process involves remapping the address of a failed memory cell to the address of a memory cell from the set of redundant memory cells.

Based on the current definition, PPR's capability is limited to one page (one row) per memory bank. The number of banks may vary depending on the memory device. For example, DDR4 memory device can have 16 banks and the number of rows per bank may vary from 1024, 2048 or 4096. To address the limited capabilities of PPR, the inventors have discovered that the protection afforded by iMS systems and methods may be a perfect complement for PPR and, in particular, may greatly enhance DDR4 memory performance.

Another restraint of PPR is that since the address of a failed memory cell must be known in order to replace it, PPR is ineffective without a mechanism that identifies addresses where memory failures have occurred in memory devices. Herein lies another opportunity for the iMS systems and methods to work in concert both with PPR and with the known technique of masking off the memory failures (e.g., see the features directed to isolating memory cells described in U.S. patent application Ser. No. 14/011,508 herein incorporated by reference).

Another technical challenge that may be associated with the testing of contemporary memory devices is how to improve the manner in which tested memory devices are identified for future use (e.g., what identifiers can be assigned to a memory device to aid in its identification after they have been tested).

In accordance with at least one embodiment described herein, there is provided a system and method of determining a set of weakest memory cells during testing of a memory device (e.g., the set comprising memory cells that fail first before other memory cells in the memory device under test), and then using a property of the weakest memory cells, such as the addresses of the n weakest memory cells, as an identifier for the memory device. In one implementation, n equals three. For example, FIG. 7 shows the 6 weakest memory cells (with 1 being the weakest, 2 being less weaker than 1 and so on) of a memory device 510 and the address locations of the three weakest memory cells (1, 2, 3) may be used to identify the memory device 510. In alternative implementations, n may be a different integer value that depends on the size of the memory device that is being identified. For example, bigger memory devices will have less of a probability of having weakest cells with the same memory addresses so n may be smaller for a larger memory device and n may be larger for a smaller memory device. Therefore, n can have a value determined based on how many memory cells are within the memory device, with n being smaller for a larger memory device compared to a smaller memory device. The addresses of the n weakest memory cells can be combined together using a known function, such as, concatenation where the memory cell addresses are listed one after the other, a hash function or other encoding or cryptographic method to create an identifier for the memory device. In some embodiments, the n weakest memory cells may be ranked starting with the weakest memory cell, the memory addresses of the n weakest memory cells can be ordered according to the ranking and then the method used to create the identifier (e.g. concatenation, a hash function, etc.) may be used on the ranked memory addresses of the n weakest memory cells to create the identifier for the memory device.

In accordance with at least one other embodiment described herein, there is also provided a novel testing procedure, which may be generally referred to as a “quick” or an “express” testing method. This quick (express) method utilizes a set of identified weakest memory cells in the memory device (see FIG. 7 for an example of six identified weakest memory cells) to determine the operational functionality of the entire memory device. In particular, the weakest memory cells are tested as a representative group of the whole set of memory cells in the memory device Therefore, if the tested weakest memory cells are determined to abruptly deteriorate (i.e., the memory cells are not slowly deteriorating, as determined by measuring parameters representing the quality of memory cells (and therefore the health of the memory device) and observing whether these parameters are changing gradually or rapidly), then the subsequent performance of a (typically more time-consuming, resource-intensive) comprehensive test of the whole memory device will be justified. On the other hand, if the tested (weakest) memory cells are deemed to be operating satisfactorily, then the remaining cells may be deemed to also be operating satisfactorily and more comprehensive testing might not be performed (although a test engineer may still choose to perform additional testing from time to time). These embodiments will allow time and resources to be saved, as the need to test the whole memory device will arise less frequently. The test parameters that may be included in the quick testing are described with relation to the example shown in FIG. 2.

### iMS for Self-Repairinq Memory Devices—Example Features

In at least one embodiment, an iMS system performs intelligent and/or background testing for memory devices having the previously described “self-repair” feature. Depending on the implementation, this application of the iMS system may also take advantage of a computing system's idle time to hide the testing (i.e., the intelligent and/or background testing can be performed during system idle time, so as not to slow down the overall operation of the computing system).

In another aspect, in at least one embodiment, for a computing system powered by battery, whether the system is connected to an AC power supply may be a relevant factor when determining whether the iMS system may perform memory testing in the background. For example, if the computing system is not connected to an AC power supply and is currently running on battery power alone, the iMS system may defer testing.

Conventionally, thorough testing of memory devices may be performed in a factory prior to deployment, and such tests may include standard tests as well as more rigorous tests in an attempt to ensure that memory devices leaving the factory are error-free. However, factory testing is expensive. Accordingly, the inventors recognized there may be advantages to performing the standard tests at the factory, while deferring further testing, to be done in the field, since an iMS system may be used to provide protection for memory devices from computer crashes caused by memory failures in accordance with the teachings herein. Thus, in at least one embodiment, the iMS system is configured to accommodate standard tests performed at the factory, and more rigorous “above-standard” tests to be performed in the field after a given memory device has been deployed.

In at least one embodiment, the iMS system may be configured to allow memory blocks to be classified (e.g., using a “Test Progress” feature). Not only are memory blocks of memory devices tested, but the memory devices can also be assigned grades. A progressive testing methodology may be employed. For example, memory devices can be tested to see if they meet a particular (low) standard of test requirements; all memory devices that meet the low standard of requirements may be provisionally assigned “grade 1”. Then, those memory devices can be further tested using a higher standard of test requirements and those memory devices that meet the higher standard of test requirements may be provisionally assigned “grade 2”, while those memory devices that fail will maintain their “grade 1” designation. The “grade 2” memory devices can then be further tested using yet a higher standard of test requirements and those memory devices that pass may be provisionally assigned “grade 3” with the failing devices maintaining their “grade 2” designation, and so on and so forth. This testing to determine the grade of the memory devices may continue until at least one or all of the memory blocks of the memory device fail a standard test at a given level or when all standard tests are completed or when a test engineer deems it is acceptable to stop this testing for grade determination (possibly due to time or resource consumption criteria).

In at least one embodiment, the iMS system may be configured to perform In-Field Retention Testing. This is one example of a memory test that may be performed to verify how long data inside a memory device remains valid before being corrupted. In particular, memory cells can be tested by postponing the interval for a refresh command, and observing whether data stored in the memory cells have become corrupted.

### Additional Features of iMS for Self-Repairinq Memory Devices

To facilitate the testing of a memory device, an iMS system may logically partition a memory device into separate memory blocks. A memory block typically refers to a contiguous memory address space consisting of a row, a half-row, or some other grouping of memory cells within an individual memory device. The iMS system may also have read/write access to a database with records containing data on the memory blocks (e.g., data identifying when each memory block was last tested, how many times each memory block was tested, how many errors were detected in each memory block and in the memory device as a whole, the addresses of corrupted memory cell locations, etc.). The iMS system may keep or otherwise manage several copies of the database records in different areas of memory or in different memory devices to protect its content from corruption due to possible memory failures.

Using the data stored in the database records, the iMS system may be configured to grade the memory blocks into different categories, as described previously, for example, ranging from a highest grade to a lowest grade. Correspondingly, memory blocks with the highest grade can be assigned to the most critical tasks, while memory blocks with the lowest grade can be kept idle where possible (e.g., see paragraphs 20 and 72-75 of Applicant's U.S. Patent Publication No. 2014/0068360 incorporated herein by reference).

Generally speaking, a self-repairing memory device will have limited repair ability. This means that there is a limit to the number of memory failures that can be repaired. When the number of memory failures goes beyond the repair limit, the computing system in which the memory device is operating may typically be configured to “prioritize” repairs. In practice, this typically involves assigning a higher priority level to repairing memory cells inside higher priority level memory blocks that have memory failures, which may include memory cell locations that, if faulty, would be most likely to cause a system crash when accessed. Therefore, by way of example, the area in a memory device where the System Boot instructions are stored may have the highest priority level, the area in the memory device where the Operating System is stored may have the second-highest priority level, the area in the memory device where User Programs are stored may have the third-highest priority level, the area in the memory device where Databases are maintained may have the fourth-highest priority level, and the area in the memory device where Entertainment media such as Pictures, Music are stored may have the lowest priority level.

An iMS system complements the hardware repair of self-repairing memory devices by providing the additional possibility of software mask-off (e.g., see paragraphs 43, 133, 134, 147, and 165 of Applicant's U.S. Patent Publication No. 2014/0068360 incorporated herein by reference). In accordance with the teachings herein, in at least one embodiment, when certain failed memory cells are in need of repair, existing (hardware) repair resources provided by the self-repairing memory device may be used until all repair resources are exhausted and/or the repair resources decrease to a resource threshold where the repair resources are reserved for future use (e.g. correction of faulty memory cells) in a higher priority level memory area. Once the memory device no longer has repair resources left that are unused or that are otherwise available, the iMS system may continue to “repair” memory failures by employing the (software) memory mask-off technique. This may involve isolating the memory failures, by holding the memory block with failed memory cells, and preventing its use by other programs. In a variant embodiment, an iMS system that is working in conjunction with a self-repairing device may reserve and apply self-repair resources to the areas (e.g. memory blocks) in a memory device where the System Boot instructions and the Operating System are stored only, while applying the software memory mask-off technique to other (e.g., lower priority level) areas or memory blocks. The priority level may be determined based on the grade of the memory block as described previously.

### Use of “Weakest” Memory Cells

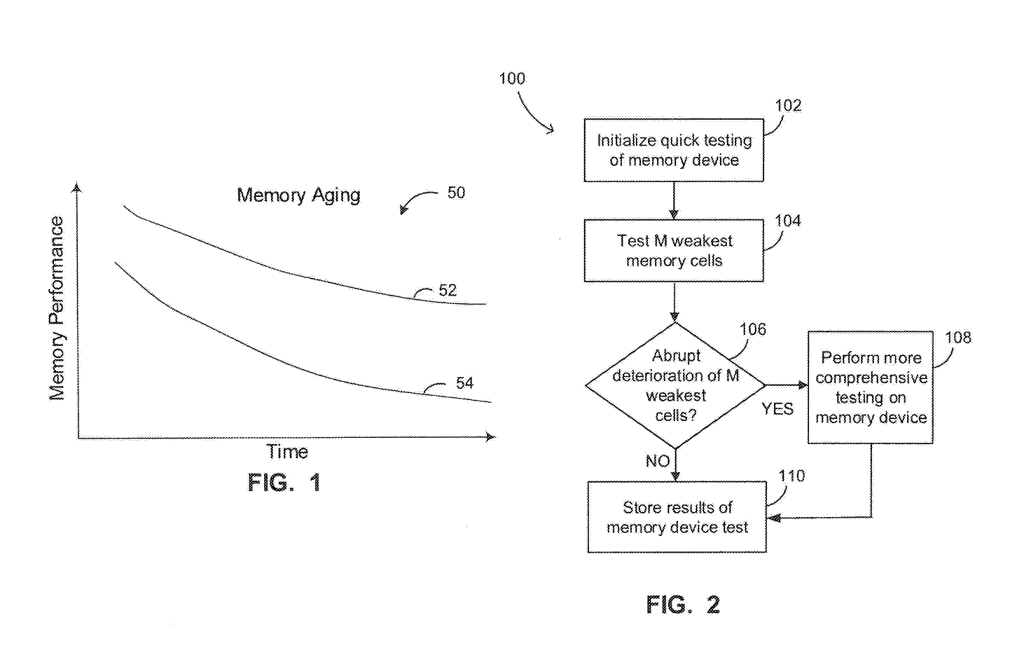

As time passes, memory devices deteriorate. Referring now to FIG. 1, shown therein is an example of memory aging in which memory performance decreases with time (shown for two different memory parameters). This means some memory cells may decay over time, and failures can develop. Before iMS techniques, known fault tolerance methodologies applied to DRAM modules were generally “passive” and “defensive,” i.e., they tried to correct or fix the issue after a memory failure event has already occurred.

However, an iMS system is based on a completely different approach. The advanced techniques used by iMS systems can be used to analyze and predict the uncorrectable failures before they occur, and initiate corrective action before a computing system might crash. For example, a predicted memory failure may result in at least one repaired memory cell or at least one isolated memory block that contains at least one faulty memory cell.

During their work with memory devices, the inventors noticed that, customarily, the decay over time and the failures of memory cells develop slowly. They subsequently recognized that it may be desirable to use the set of the weakest memory cells, as determined during testing, as a footprint to identify the tested memory devices.

More specifically, it was learned that during the operational lifespan of memory devices, the set of weakest memory cells usually stay the same. Thus, tested memory devices may be identified by a set of weakest memory cell addresses (e.g., the addresses of the weakest n cells). In one embodiment, n is three. However, in other embodiments n may also be another integer value as described previously.

Generally, a set of weakest memory cells determined during testing of a memory device (e.g., the set comprising cells that fail first before other cells in the device under test) can be used, and then a property of the memory cells in this set of weakest memory cells such as, but not limited to, the addresses, voltages, memory operating clock frequency and temperature of the n weakest memory cells, for example, can be recorded where the addresses of the weakest memory cells can be used as an identifier for the memory device as explained previously. This identifier may also be used in conjunction with other identifiers (e.g., a manufacturer serial number for a memory device) to facilitate identification of the memory device. In one embodiment, n is a pre-determined, fixed size.

Moreover, if it is determined (e.g., upon further testing) that the identities of the weakest memory cells of a memory device are changing with the passing of time, then this would typically mean that the memory device is behaving abnormally, and further comprehensive testing of the memory device is likely justified in those situations. The comprehensive testing may comprise testing of the whole memory device using more extensive test patterns.

### Quick or Express Memory Testing

During their work with memory devices, the inventors also realized that the typical slow decay over time of memory cell performance can justify, most of the time, the regular testing of only a few representative memory cells as a close substitute for checking the integrities of all of the memory cells of a memory device as a whole. A novel testing procedure performed on this basis is generally referred to herein as a quick or an express testing procedure.

Referring now to FIG. 2, shown therein is an example embodiment of a quick test method 100 in accordance with the teachings herein The quick test method 100 may involve initialization in which the n weakest memory cells are defined for testing, where n may be an integer such as 3 for example, based on the example shown in FIG. 7. Alternatively, n may have another value depending on the size of the memory device that is being tested. At act 104, initially testing, for example, is done on a number of identified “weakest” memory cells (e.g., the three weakest memory cells of a memory device) to assess the operational functionality of the entire memory device. In other words, in accordance with the quick testing method 100, the weakest memory cells are used as a representative group for the complete set of memory cells of the memory device. If at act 106 the weakest memory cells tested according to the quick testing procedure are determined to abruptly deteriorate, then a further comprehensive test of the whole memory device will be justified and may be performed at act 108. Abrupt deterioration may be determined by performing absolute and/or relative measurements and comparing them with standard values determined by a standards testing body for the particular memory device being tested. An absolute measurement measures the magnitude value of a parameter whereas a relative measurement measures how a parameter's value changes over time.

In one example embodiment, the testing involves measuring data retention capability which tests how long a memory cell can hold a logic value correctly without needing a refresh. Testing the data retention capability can be part of testing the performance of the memory device. A test engineer may determine that abrupt deterioration has occurred based on their experience or comparing the test values with threshold values that are determined as part of a standard for this type of memory being tested. Poor data retention capability (or memory cell weakness) may be caused either by leakage or by cross interference with neighboring memory cells. Other memory performance tests may include: memory clock frequency tests in which the memory clock frequency is increased until the memory device fails, or tests with decreasing time delays in read or write operations until the memory device fails (e.g. the row-to-column delay between row activation and starting to reading data in the row is decreased until the memory device fails).

On the other hand, if the tested (weakest) memory cells are deemed to be operating satisfactorily, then the remaining memory cells may also be deemed to be operating satisfactorily and more comprehensive testing might not need to be performed (although a test engineer may still decide that more comprehensive testing is to be performed, from time to time). In either case, the memory test results for the memory device may be optionally saved at act 110. These quick testing embodiments will allow time and resources to be saved, as the need to test the whole memory device will arise less frequently.

The quick or express memory testing procedure described above is part of an intelligent memory testing method supported by iMS in accordance with the teachings herein. The intelligent memory testing method includes maintaining a database of records containing data associated with tested memory devices and statistics of the memory failures such as, but not limited to, when the memory device was tested, what kind of tests were performed, which tests were passed and which tests were failed, for example.

### Effective Memory Testing

Based on the memory test statistics of the quick test method 100, test engineers can also choose particular test patterns and test procedures to perform an effective or “optimized” memory test method 150 (as distinguished from the quick (express) or the comprehensive testing) that generally has two stages. The first stage involves using test statistics of memory failures for memory devices in order to determine which test patterns are more effective in testing a particular memory device, as described in act 154. The second stage involves testing and obtaining absolute and/or relative measurements as described in act 156 based on the test patterns determined in the first stage. The test results can then be compared to test results based on memory testing standards for the particular memory device being tested to determine if any memory cells are faulty or weak. Testing may be done once a week or every day and the test measurements results may be recorded in a test statistics database.

Effective testing will save time and resources compared to a more complete, comprehensive memory test as well as allowing for a comprehensive test of the entire memory device to be performed less frequently. As compared to the quick (express) memory test, which is considered quick in that the range of memory cells to be tested is reduced, the effective memory testing described herein may save time and resources by reducing the depth of test thoroughness (e.g. less test patterns are used) relative to a comprehensive memory test.

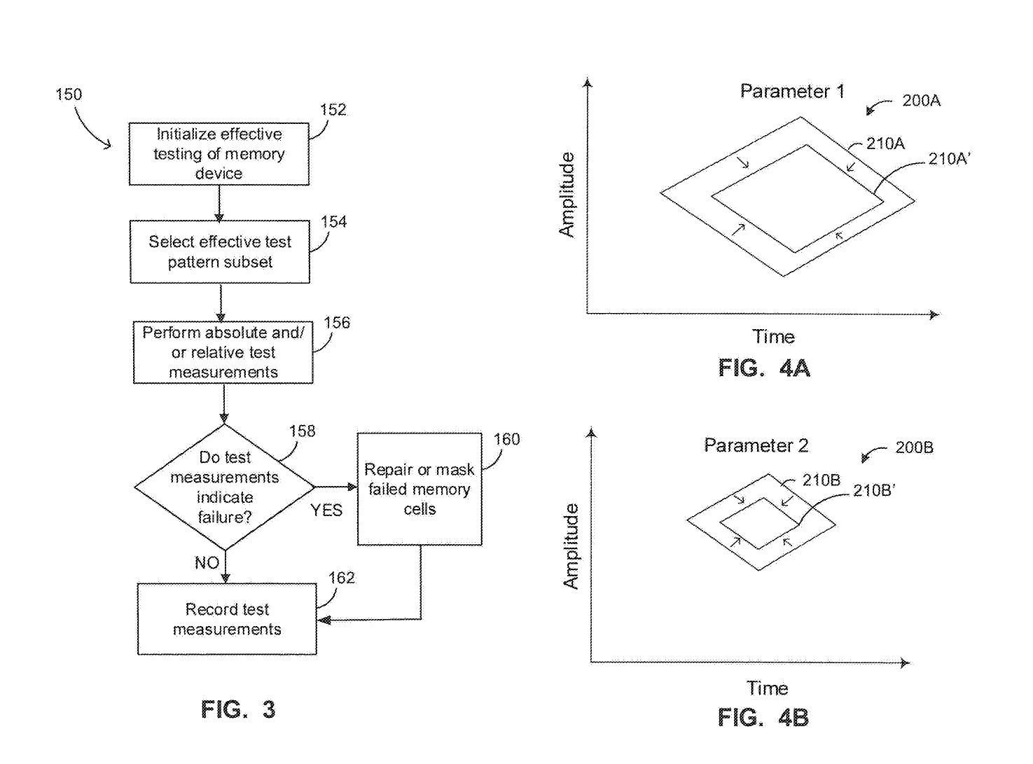

Referring now to FIG. 3, shown therein is an example embodiment of the effective memory test method 150. At 152, the effective memory test 150 is initialized. This may include selecting the type of memory testing to perform, such as, but not limited to, one or more of measurement of data valid windows, leakages between I/O pins, cross talk between I/O pins, data retention (as explained previously) and others. The type of memory tests selected at 152 for the effective memory test 150 may cover the most common memory failures (i.e. a memory cell not being operational) that are occurring, according to the test statistics database.

At 154, the test engineers select certain test patterns to be performed such as selecting from a subset of test patterns that are more effective in detecting faulty memory cells. For example, if there are 10,000 test patterns and a first test pattern subset has 9,900 test patterns that catch about 5% of all of the faulty memory cells for a given type of memory device while a second test pattern subset has 100 test patterns that catch 95% of all of the faulty memory cells for the given type of memory device, then the effective testing may be performed using the second test pattern subset. Since the second test pattern subset is much smaller than the first test pattern subset, then the effective memory testing will take less time than a conventional memory test. These test statistics may be kept in a test statistics database that is consulted when trying to determine the best test patterns to use in effective testing at act 154, which is the smallest number of test patterns that catches that largest percentage of faulty memory cells.

At act 156 measurements are performed on certain parameters to determine which memory cells may be faulty or weak. At act 156, the absolute and/or relative magnitude of test parameters, such as but not limited to timing parameters and/or voltage parameters, for example, may be measured. Examples of timing parameters that may be measured during testing include one or more of the refresh interval, the read latency, the write latency and the row-to-column delay. Examples of voltage parameters that may be measured during testing include one or more of the power supply voltage to the memory device (V_{DD}), power supply voltage to the I/O pins (V_{DDQ}), and the comparison voltage level used to determine logical values (V_{REF}). The “absolute” measurements can be performed to ensure that test parameters of a memory device are positioned within a range allowed by the memory standards, whereas the “relative” measurements can be performed to evaluate changes of the measured test parameters with the passage of time for the memory device. For example, FIGS. 4A and 4B show data valid windows 210A and 210B for parameters 1 and 2, respectively, over time. The dimensions of the data valid windows 210A and 210B decrease over time to data valid windows 210A′ and 210B′ due to the memory aging in this example and progressively worsen until the memory cells become bad (e.g. permanently faulty and not useful).

At act 158, it is determined whether the test measurements are within acceptable levels based on industry standard practice. If the test measurements indicate that the tested memory device has faulty memory cells then the method 150 proceeds to act 160 where the faulty memory cells are repaired or the memory blocks that contain these faulty memory cells are masked off. Otherwise, if the test measurements do not indicate that the tested memory devices have faulty memory cells then the method 150 proceeds to act 162 to record the test measurements.

At 160, the decision of repairing the faulty memory cells may depend on if there are enough repair resources to do so. If so, then the faulty memory cells can be repaired. If the repair resources are nearing depletion and if the faulty memory cells needing repair might be used to store information that is crucial for proper operation of a computing system that uses the memory device, then the faulty memory cell may still be repaired with the remaining repair resources or by using other resources. If there are not enough repair resources and the faulty memory cells are not used for critical operations, then the memory blocks containing the faulty memory cells can be masked off so that they are not used during operation. The method 150 then proceeds to act 162 to record the test results.

At act 162 the memory test statistics can be stored and associated with previously tested memory devices in the test statistics database, and/or stored and associated with previous test results for multiple testing sessions for the tested memory device, either in the same database or in one or more separate databases.

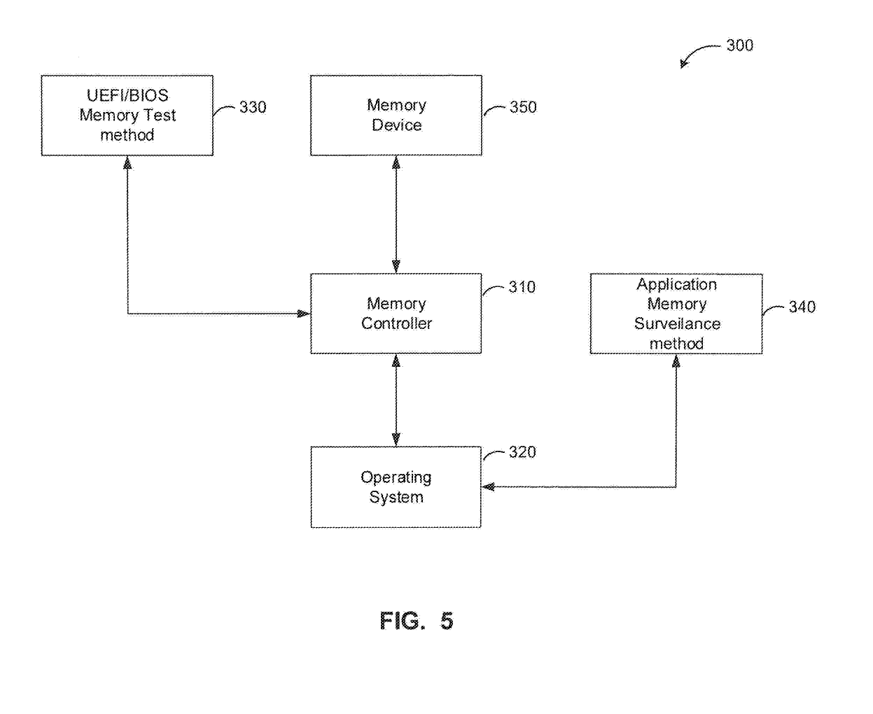

Referring now to FIG. 5, shown therein is an example embodiment of a computing system 300 that includes example memory testing components in accordance with the teachings herein. The computing system 300 comprises a memory controller 310 (currently part of the CPU) that communicates with the memory device 350. The computing system 300 also comprises two memory testing components: a Unified Extensible Firmware Interface/Basic Input/Output Operating System (UEFI/BIOS) memory testing method 330 and an Application memory surveillance method 340. In alternative embodiments, at least one of the memory test components may be used to perform the quick testing method 100 and/or the effective testing method 150. The UEFI/BIOS memory testing method 330 is a BIOS component that operates during the BIOS stage when a computing system that uses the memory device 350 is booting up. The Application memory surveillance method 340 operates while the Operating System 320 is normally operating. The memory controller 310 is part of the CPU of the computing system 300. At least one of the UEFI/BIOS memory test method 330 and the Application memory surveillance method 340 may be implemented by software programs that use the memory controller 310 to perform certain tests. The methods 330 or 340 may be executed in concert with the memory controller 310 or another processing device of the computing system 300. Alternatively, at least one of the UEFI/BIOS memory test method 330 and the Application memory surveillance method 340 may be implemented by hardware such as by an ASIC or an FPGA.

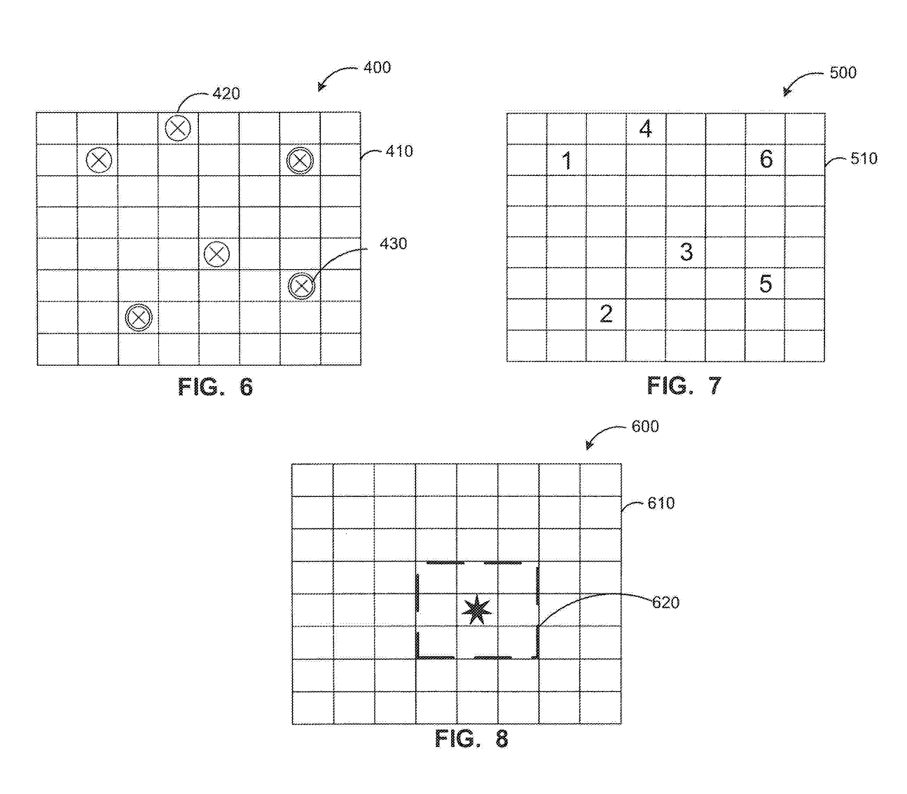

The UEFI/BIOS memory test method 330 accesses the memory device 350 via the memory controller 310 during bootup of the computer system 300, tests the memory device 350 and isolates/repairs memory failures. The actual repair function may be done by the memory controller through BIOS commands and is outside of the scope of this application. The UEFI/BIOS memory test method 330 may perform isolation or masking off failed memory cells by preparing a memory mapping table and excluding the failed memory cell locations from the memory mapping table. The memory mapping table is used by the Operating System 320 to determine which memory cells may be used during operation. FIG. 6 shows an example of repaired memory cells (one of which is identified by reference numeral 420) and masked-off memory cells (one of which is identified by reference numeral 430) when memory cells of a memory device 410 having memory failures are identified and processed.

The Application memory surveillance method 340 accesses the memory device 350 via the Operating System 320 and the memory controller 310 during the normal operating stage of the Operating System 320 during which the Application memory surveillance method 340 tests the memory device 350 and isolates/repairs memory failures. Repair may again be done by the memory controller 310 through Operating System commands. Isolation may be done by the Application memory surveillance method 340 recording the location of memory blocks with failed memory cells and preventing access to these memory blocks containing bad (also known as failed or faulty) memory cells by other application programs and the Operating System 320 itself. These recorded locations may be stored in a persistent memory element.

In at least one embodiment, act 104 of the quick (express) testing method 100 or act 156 of the effective testing method 150 may perform testing that involves taking both absolute and relative measurements. As previously noted, absolute measurements are performed to ensure that test parameters are within an allowed range. It may be feasible to perform absolute measurements in order to identify which memory cells are the weakest memory cells for a given memory device, since the weakest memory cells will usually be the first memory cells that fall outside of the allowed range. When the quick or express testing is performed again at a future point in time on the same memory device, certain tests might only be performed only on the previously determined weakest memory cells (this may be determined during the initialization act 102 of the quick test method 100).

On the other hand, relative measurements track changes in test parameters with the passage of time. If the changes are considerable, as determined by the test engineer according to his/her expertise and standard values for test results, then it may mean that the memory device is deteriorating in an abnormal manner. In that situation, comprehensive testing of the memory device may most likely be justified.

When performing relative measurements as part of a testing procedure, a test engineer can also perform such measurements only on a set of weakest memory cells during act 104 of the quick or express testing method 100. However, a test engineer can test other sets of memory cells (i.e., memory cells not determined to belong to the set of weakest memory cells) during quick or express testing as well. For example, a test engineer can perform relative measurements on a set of random memory cells during act 104 of the quick or express testing method 100.

Usually, an iMS system is able to isolate memory cells having memory failures and prevent their usage so that other failures do not occur. However, in some circumstances, it may not be possible to conventionally isolate memory blocks having failed memory cells. These are failures of memory cells that are used by critical tasks which results in system crashes, i.e. faults originated in a core system drivers or the operating system itself. Alternatively, memory failures may be newly developed and the memory cells having these failures may be accessed by applications before they can be caught. Such errors may lead to General protection faults or “Blue Screen” failures.

For these types of memory failures, the computing system 300, may implement an iMS system in accordance with the teachings herein that acquires information about the memory failures (including the faulty memory cell locations and error codes) from the Operating System records. The computing system 300 may test these faulty memory cells as well as nearby memory cells and isolate memory blocks having bad memory cells during the BIOS stage of the next computing system bootup. The computing system 300 may perform this testing as part of the quick testing method 100, which may be performed, in some cases, as an after-crash testing method in which case act 102 of the quick testing method is revised to acquire information about the memory failures from the operating system records and indicate these faulty memory cells for testing during initialization.

At least some of the embodiments of intelligent memory testing described in accordance with the teachings herein may allow for the saving of time and resources by testing the complete memory device less frequently. However, intelligent memory testing may not uncover all possible memory failures. Thus, the comprehensive testing of the memory device may also be performed by test engineers from time-to-time. Nevertheless, by applying an intelligent testing procedure in accordance with at least one embodiment described herein, the comprehensive testing would need to be performed less frequently than would otherwise be required, if an intelligent testing procedure were not employed.

While the Applicant's teachings described herein are in conjunction with various embodiments for illustrative purposes, it is not intended that the Applicant's teachings be limited to such embodiments. On the contrary, the Applicant's teachings described and illustrated herein encompass various alternatives, modifications, and equivalents, without departing from the embodiments described herein, the general scope of which is defined in the appended claims.

1. A method of identifying a memory device that is used by a computing system, the memory device having memory blocks containing memory cells, the method comprising:
testing the memory device to determine weakest n memory cells based on performance testing; and
creating an identifier for the memory device based on using memory addresses of the n weakest memory cells.

2. The method of claim 2, wherein n has a value determined based on how many memory cells are within the memory device, with n being smaller for a larger memory device compared to a smaller memory device.

3. The method of claim 2, wherein the method further comprises concatenating the memory addresses of the n weakest memory cells to create the identifier.

4. The method of claim 2, wherein the method further comprises applying at least one of a hash function and an encryption method on the memory addresses of the n weakest memory cells to create the identifier.

5. The method of claim 2, wherein the method further comprises ranking the n weakest memory cells starting with the weakest memory cell and ordering the memory addresses of the n weakest memory cells according to the ranking and creating the identifier based on the ranked memory addresses.

6. A method of testing a memory device that is used by a computing system, the memory device having memory blocks having memory cells, the method comprising:
initializing test parameters to reduce how much testing is done compared to a comprehensive memory test;
testing performance for the memory device using tests defined by the test parameters to identify memory blocks having at least one faulty memory cell; and
performing a corrective action on the identified memory blocks.

7. The method of claim 6, wherein the initialization act comprises selecting faulty memory cells that resulted in a crash of an operating system of the computing system, the testing and the performing of the corrective action occurs during a bootup process of the computing system after the operating system crash and the performing comprises repairing or isolating the faulty memory cells that resulted in the crash.

8. The method of claim 6, wherein the initialization comprises determining a set of n weakest memory cells or a set of n randomly chosen memory cells to act as n representative memory cells for the memory device; and performing the testing on the set of n representative memory cells.

9. The method of claim 8, wherein if the testing of the n representative memory cells determines an abrupt deterioration of the n representative memory cells, then the method further comprises performing comprehensive memory testing.

10. The method of claim 6, further comprising storing the test results in a test statistics database and comparing test results taken at different times to determine how quickly the memory device is deteriorating.

11. The method of claim 6, wherein the act of initializing the testing comprises selecting a smaller subset of test patterns that are more likely to locate faulty memory cells based on test statistics from previous testing.

12. The method of claim 6, wherein the corrective action comprises repairing the at least one faulty memory cell if it is located in a high priority level memory block.

13. The method of claim 6, wherein the corrective action comprises repairing faulty memory cells until all repair resources are exhausted or meet a resource threshold where the repair resources are reserved for future repair of memory cells in a higher priority level memory area.

14. The method of claim 12, further comprising determining a priority level for a given memory cell based on a highest standard of performance requirements met by a given memory block that includes the given memory cell.

15. The method of claim 12, further comprising assigning a high priority level for a given memory cell that is used in the bootup of the computing system or the given memory cell is used by an operating system of the computing system.

16. The method of claim 12, further comprising assigning a high priority level for a given memory cell according to a risk of system crash due to a memory failure of the given memory cell.

17. The method of claim 12, further comprising assigning a highest priority level for a given memory cell used to store system boot instructions, assigning a second highest priority level to the given memory cell when it stores operating system instructions, assigning a third highest priority level to the given memory cell when it stores user programs and assigning a fourth highest priority level to the given memory cell when it stores database records.

18. The method of claim 6, wherein the corrective action comprises masking the identified memory block having at least one faulty memory cell so that it is isolated and not used during operation if the at least one memory cell cannot be repaired or the at least one memory cell resides in a lower priority level memory area.

19. The method of claim 6, wherein the act of testing comprises performing more rigorous above-standard tests in the field after the memory device has been deployed from manufacturing.

20. The method of claim 6, wherein the method comprises a two stage test with a first stage where the act of initializing comprises selecting a smaller number of memory cells to test and a smaller number of test patterns for testing compared to a comprehensive memory test and the second stage comprises performing the testing.

21. A computing system that tests performance for a memory device having memory blocks with memory cells, the computing system comprising:
a memory controller that is coupled to the memory device and is configured to enable testing of the memory device;
an operating system for controlling operation of the computing system; and
test components that are configured to test performance of the memory device using a reduced amount of testing compared to a comprehensive memory test and to perform a corrective action on memory cells located in one or more of the memory blocks.

22. The computing system of claim 21, wherein the test components are configured to test a set of n representative cells for a given memory block to determine the performance of the given memory block, the set of n representative cells representing n weakest memory cells or n randomly selected memory cells.

23. The computing system of claim 21, wherein the test components are configured to perform testing using a smaller subset of test patterns than a comprehensive memory test that are more likely to locate faulty memory cells based on test statistics from previous testing.

24. The computing system of claim 21, wherein the corrective action comprises repairing or masking and the test components are configured to repair the at least one faulty memory cell if it is located in a high priority level memory block or mask the memory block containing the at least one faulty memory cell if it is a low priority level memory block.

25. The computing system of claim 21, wherein the high priority level memory block is an area of the memory device that is used in the bootup of the computing system or that is used by the operating system.

26. The computing system of claim 21, wherein the test components are configured to select a smaller number of memory cells in a given memory block to test and use a smaller number of test patterns for testing compared to the comprehensive memory test.

27. A computer readable medium comprising a plurality of instructions that are executable by a processor of a computing system, wherein the plurality of instructions implement a method of testing a performance of a memory device, wherein the method comprises:
initializing test parameters to reduce how much testing is done compared to a comprehensive memory test;
testing performance for the memory device using tests defined by the test parameters to identify memory blocks having at least one faulty memory cell; and
performing a corrective action on the identified memory blocks.

28. The computer readable medium of claim 27, wherein the method further comprises selecting n representative cells for a given memory block using n weakest memory cells or n random memory cells of the given memory block; and testing the set of n representative cells to determine the performance of the given memory block.

29. The computer readable medium of claim 27, wherein the method comprises performing testing using a smaller subset of test patterns than a comprehensive memory test that are more likely to locate faulty memory cells based on test statistics from previous testing.

30. The computer readable medium of claim 27, wherein method comprises performing repairing or masking as the corrective action, the repairing being done on the at least one faulty memory cell if it is located in a high priority level memory block and the masking being done if at least one faulty memory cell is in a low priority level memory block.

31. The computer readable medium of claim 27, wherein the method comprises selecting a smaller number of memory cells in a given memory block to test and using a smaller number of test patterns for testing compared to the comprehensive memory test.
